(19) United States
(12) Patent Application Publication
(10) Pub. No.: US 2008/0060831 A1
(43) Pub. Date: Mar. 13, 2008

(54) Outlet cover

(76) Inventors: Karla Moore, Kennesaw, GA (US); Sean Moore, Kennesaw, GA (US)

Correspondence Address: MYERS & KAPLAN;INTELLECTUAL PROPERTY LAW, L.L.C., CUMBERLAND CENTER II, 3100 CUMBERLAND BLVD , SUITE 1400, ATLANTA, GA, 30339, US

(21) Appl. No.: 11/899,993

(22) Filed: Sep. 7, 2007

Related U.S. Application Data
(60) Provisional application No. 60/824,866, filed on Sep. 7, 2006.

(51) Int. Cl. H05K 5/03

(52) U.S. Cl. 174/67

(57) ABSTRACT

A cover for an electrical outlet is disclosed that prevents insertion of dangerous foreign objects into the sockets of the outlet, which would pose a shock hazard. The cover is configured such that it allows use of either or both of two sockets of the electrical outlet. The cover is further designed such that it is safe for handling by children.

### RELATED APPLICATIONS

The present U.S. Non-Provisional utility application is related to, and hereby claims priority to, and the full benefit of, U.S. Provisional application entitled Outlet Cover, having assigned Ser. No. 60/824,866, filed Sep. 7, 2006, on behalf of Sean and Karla Moore, incorporated herein by reference.

### BACKGROUND OF THE INVENTION

1. Technical Field

The present invention relates generally to an outlet cover, and more particularly, to a child-proof safety cover for an electrical outlet.

2. Description of Related Art

The widespread implementation of electricity in residential and commercial structures has created an inherently dangerous risk of electric shock and/or electrocution. While defective electrically powered devices and faulty wiring account for some of the risk, most injuries result from the insertion of foreign objects into the socket of an electrical outlet. The risk is greater when children are present, because children are unable to appreciate the risk of insertion of foreign articles into the sockets of an electrical outlet. Furthermore, these outlets are typically installed in locations that are easily accessible to children, such as the floor, the baseboard, or in lower portions of a wall.

Although risk of injury due to shock from an electrical outlet is reduced by the advent and implementation of ground fault interrupter outlets, these outlets nonetheless allow some current to flow before the ground fault is detected and the circuit is broken. This current may be sufficient to injure or kill a child or other individual. Furthermore, ground fault interrupter outlets, like any safety precaution, are not infallible. Therefore, in order to increase the level of safety of electrical outlets, particularly where they are accessible by children, redundant safety systems should be employed.

In addition to ground fault interrupter outlets, non-conducting physical barriers have been implemented to prevent insertion of foreign objects into the sockets of an electrical outlet. Unfortunately, such barriers are typically small in size: roughly the size of a single socket. As a result, the barriers are easily misplaced when outlet is in use, and further, the non-engaged barriers present a choking hazard for children due to the barriers' small size.

Thus, it is readily apparent that there exists an unmet need for a device for preventing accidental or intentional insertion of foreign objects that pose a threat of electrical shock or electrocution into a socket of an electrical outlet that allows use of one or both sockets of an electrical outlet, that is designed to reduce the risk of loss of the device, and that is designed to be safe if handled by a child.

### BRIEF SUMMARY OF THE INVENTION

Briefly described, in a preferred embodiment, the present invention overcomes the above-mentioned disadvantages and meets the recognized need for such a device by providing an outlet cover that is larger than a single socket of an electrical outlet and that allows for selective use of one or more sockets of an electrical outlet while covering other sockets of the electrical outlet.

According to a first aspect of the present invention, an outlet cover comprises a planar body having a transverse groove disposed therein and at least one projection adapted to engage a first socket of an electrical outlet, such that the planar body is retained in a position covering at least one socket of the electrical outlet, wherein the planar body can be bent along a line defined by the groove such that at least one socket of the electrical outlet is exposed while the at least one projection engages the first socket.

According to another aspect of the present invention, the outlet cover comprises an electrically insulating material.

According to yet another aspect of the present invention, the outlet cover is sized such that all sockets of the electrical outlet are covered when the projection engages one of the sockets.

According to yet another aspect of the present invention, the outlet cover is configured such that each portion of the outlet cover defined by the groove is large enough to prevent a child from swallowing the portion if it breaks off from the outlet cover at the groove.

According to another aspect of the present invention, a spring mechanism may be implemented to ensure closure of cover plate over socket when socket is not in use. The spring mechanism may be operable with one or more portion(s) of the planar body to provide a biasing force.

According to another aspect of the present invention, the cover plate may have removable projection inserts to facilitate various configurations thereof for use for different size and number sockets. As a result, the cover plate may be implemented in any standard domestic or international electrical outlet.

According to another aspect of the present invention, a method of using the outlet cover comprises the steps of engaging a projection of the outlet cover with a socket of an electrical outlet and bending the outlet cover along a line defined by a groove in the outlet cover, thereby exposing a second socket of the electrical outlet.

These and other objects, features, and advantages of the invention will become more apparent to those ordinarily skilled in the art after reading the following Detailed Description of the Invention and Claims in light of the accompanying drawing Figures.

### BRIEF DESCRIPTION OF THE DRAWINGS

Accordingly, the present invention will be understood best through consideration of, and reference to, the following Figures, viewed in conjunction with the Detailed Description of the Preferred Embodiment referring thereto, in which like reference numbers throughout the various Figures designate like structure and in which:

FIG. 1 is a perspective view of an outlet cover according to the present invention;

FIG. 2 is a side view of the outlet cover of FIG. 1;

FIG. 3 a rear view of the outlet cover of FIG. 1;

FIG. 4 is a side view of the outlet cover of FIG. 1 in a bent state;

FIG. 5 is a flowchart illustrating a method of using the outlet cover of FIG. 1; and

FIG. 6 is a front view of an outlet cover according to an alternate configuration.

It is to be noted that the drawings presented are intended solely for the purpose of illustration and that they are, therefore, neither desired nor intended to limit the invention to any or all of the exact details of construction shown, except insofar as they may be deemed essential to the claimed invention.

### DETAILED DESCRIPTION OF THE INVENTION

In describing preferred embodiments of the present invention illustrated in the Figures, specific terminology is employed for the sake of clarity. The invention, however, is not intended to be limited to the specific terminology so selected, and it is to be understood that each specific element includes all technical equivalents that operate in a similar manner to accomplish a similar purpose.

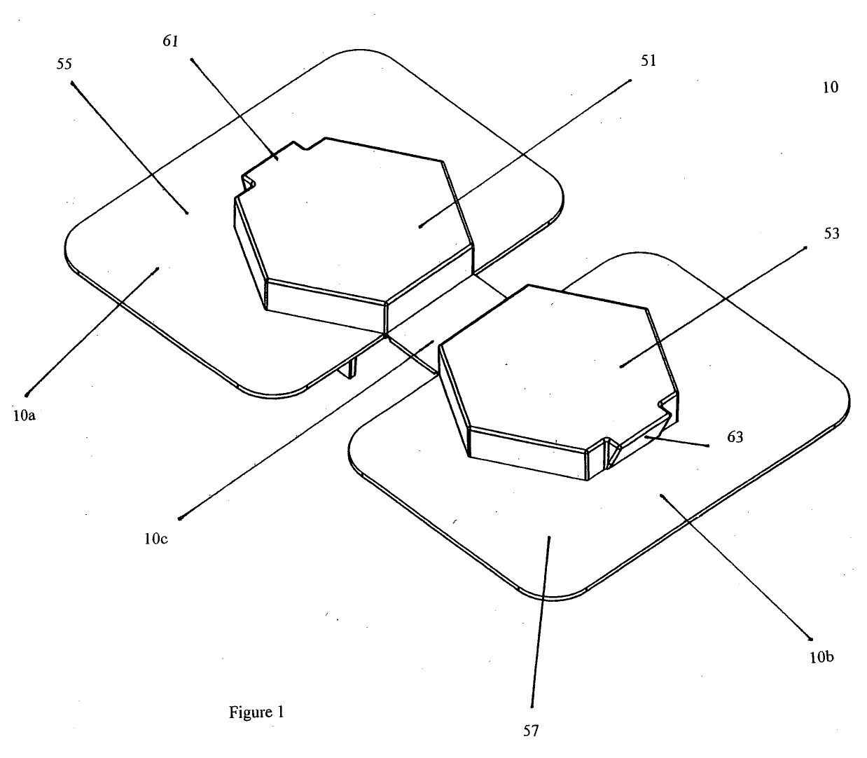

In that form of the preferred embodiment of the present invention chosen for purposes of illustration, FIGS. 1-4 show outlet cover 10 having a generally rectangular shape, but may include a rounded shape, such as circular or oval, or other desired shape, including decorative shapes. The shape of outlet cover 10 is preferably congruent with the shape of an electrical outlet with which outlet cover 10 is intended to be used. The size of outlet cover 10 is also preferably congruent with, or larger than, the size of the electrical outlet with which outlet cover 10 is intended to be used. It is contemplated that the outlet cover 10 may be used with single-socket or multiple-socket electrical outlets, and with electrical outlets of various types, including those with NEMA, JIS, CEE, and BS types of sockets, among others. Preferably, outlet cover 10 comprises an electrically insulating material such as a plastic, rubber, or other natural or synthetic electrically insulating material.

Also shown in FIGS. 1-4 is groove 20 formed in outlet cover 10. As illustrated in FIG. 1, groove 20 preferably extends laterally across a middle of outlet cover 10. Groove 20 may be formed by removing a portion of the material where the groove 20 is to be formed, or, alternatively, groove 20 may be formed by molding, or otherwise created contemporaneously with outlet cover 10. Groove 20 defines first portion 10a of outlet cover 10 and second portion 10b of outlet cover 10. Groove 20 preferably further defines a weaker portion of outlet cover 10, whereby first portion 10a and second portion 10b may be bent out of parallel alignment. Groove 20 may optionally be frangible, whereby one of first portion 10a and second portion 10b may optionally be removed from outlet cover 10. Optionally, two or more grooves 20 may be included, such as to increase a range of motion of one or more of first portion 10a and second portion 10b, and may define third portion 10c between first portion 10a and second portion 10b.

Each of first portion 10a and second portion 10b preferably includes generally rectangular thin portion 55, 57, respectively and a thicker raised portion 51, 53, respectively. Each of thin portions 55, 57 may be flexible if desired to allow thin portions 55, 57 to conform to an outlet or outlet cover to which it may be attached. Raised portions 51, 53 are preferably rigid and are preferably disposed proximate prongs 30a, 30b respectively, and preferably provide a secure base or attachment point for prongs 30a, 30b respectively. Additionally, means 61 and 63 for bending first portion 10a and second portion 10b, respectively may be included on each of raised portions 51, 53, respectively, whereby a user may apply a force to bend a respective one of first portion 10a and second portion 10b out of a co-planar arrangement. As will be understood by those ordinarily skilled in the art, means 61 and 63 may be formed elsewhere on first portion 10a and 10b respectively, and may take other forms, so long as application of a bending force may be accomplished.

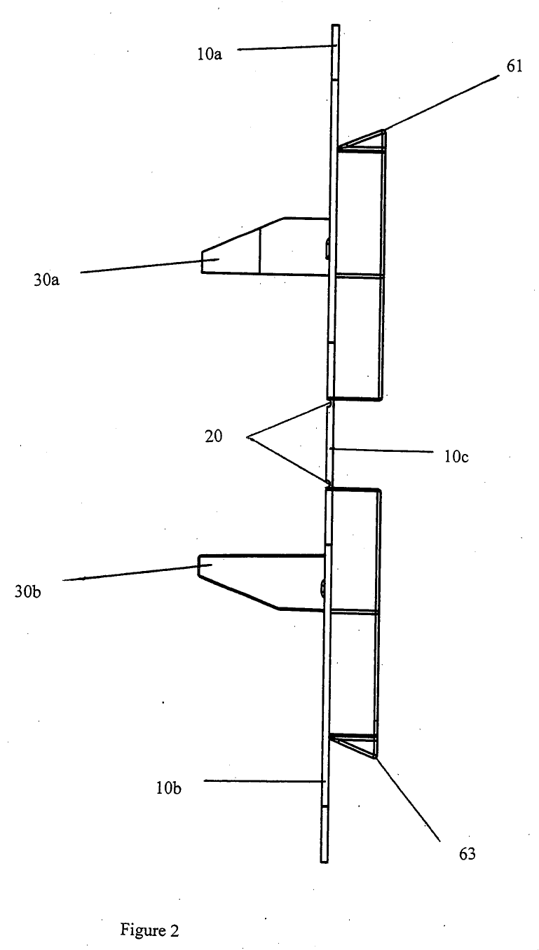

Now referring more particularly to FIG. 2, the outlet cover 10 is shown from the side, illustrating a thickness of first portion 10a and second portion 10b, and a lesser thickness of grooves 20. In FIG. 2, grooves 20 are shown as being v-shaped, although grooves 20 may be configured in any shape or dimension suitable to enable first portion 10a and/or second portion 10b to bend and expose one or more sockets for use. Also shown are prongs 30a and 30b, which project from a back side surface of first portion 10a and second portion 10b, respectively. Prongs 30a and 30b are configured to engage a socket of an electrical outlet. As shown in FIG. 2, prongs 30a and 30b are configured to engage respective ones of two sockets of an electrical outlet. Prongs 30a and 30b are preferably sized such that engagement with a socket of an electrical outlet provides sufficient frictional or other mechanical force to retain outlet cover 10 attached to the electrical outlet. In this configuration, either one of first portion 10a or second portion 10b may be bent out of parallel alignment with the other portion, thereby disengaging the respective prong from the socket, exposing the socket for use with a plug of an electrical device.

Prongs 30a and 30b are preferably provided with at least one feature, such as relief cuts, flexible material, sufficiently short length, taper, or similar structural designs or material characteristics to facilitate such hinged removal from engagement with the socket. Alternatively, one of prongs 30a and 30b may be omitted or removable, and outlet cover 10 may be retained covering all the sockets of a particular electrical outlet by a single prong, whereby during use only the portion from which the prong was omitted may be bent, thereby exposing the socket for use. One or more of prongs 30a and/or prongs 30b may be removably attached to respective first portion 10a and second portion 10b via threads, friction fit engagement, or the like, whereby a user may selectively position prongs on outlet cover 10, for example to conform to a receptacle pattern with which use is desired. It is also contemplated that groove 20 may extend vertically across outlet cover 10, in order to enable selective exposure of horizontally arranged sockets, or pairs of sockets.

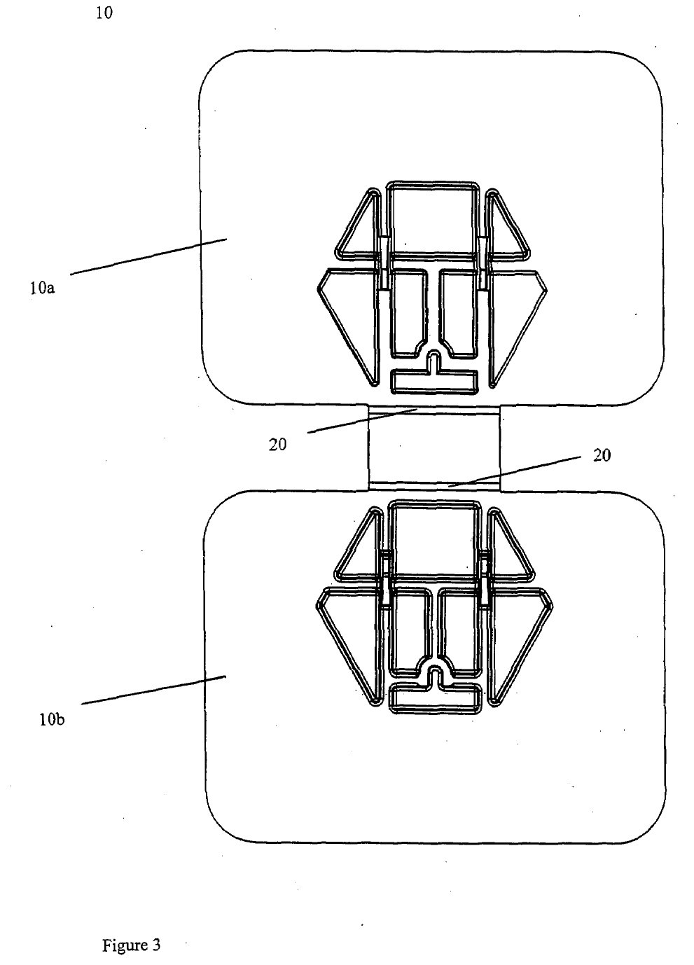

FIG. 3 shows prongs 30a and 30b as pairs of prongs. Prongs 30a and 30b may consist of one or more projections, limited in number and arrangement only by the socket with which outlet cover 10 is intended to be used. Preferably, however, outlet cover 10 has only as many projections as necessary to securely cover the sockets of an electrical outlet, and preferably such projections are spatially arranged so as to increase use of outlet cover 10 with the number of different types of socket types and electrical outlet configurations possible. This enables a user to use outlet cover 10 in different locations within a structure, or even in various structures, wherever electrical outlets need to be covered. Alternatively, as discussed above, one or more projections may be removable, such as via threaded engagement, friction-fit engagement, or the like, or may be selectively configurable, such as via a locking engagement, adhesive, welding, or the like.

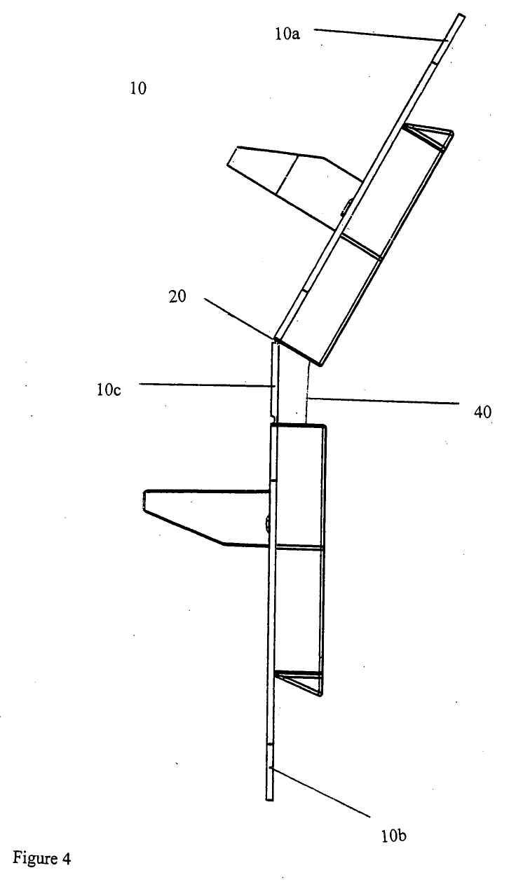

FIG. 4 shows first portion 10a bent out of parallel alignment with second portion 10b. In the arrangement of FIG. 4, outlet cover 10 is retained in position by prong 30b engaged with a lower socket of an electrical outlet. Portion 10b is bent far enough out of parallel alignment with portion 10b to allow a plug of an electrical device to engage an upper socket of the electrical outlet. When the device is no longer in use, the plug may be removed, and first portion 10a may be bent back into alignment with second portion 10b and prong 30a may engage the upper socket of the electrical outlet. Such bending back into alignment may be accomplished via biasing means 40, such as spring, a pneumatic element, a hydraulic element, a resilient member, combinations thereof, or the like, wherein biasing means 40 preferably provides a force on at least one of first portion 10a and second portion 10b, at lease when first portion 10a is not parallel with second portion 10b, such that outlet cover 10 may automatically cover at least one socket proximate first portion 10a and at least one socket proximate second portion 10b.

Alternatively, if use of both sockets is needed, prong 30b may be disengaged from the lower socket of the electrical outlet, freeing both sockets for use with electric devices. In that case, outlet cover 10 is large enough that it is not easily misplaced, and does not present a choking hazard to children. In a case where one of first portion 10a and second portion 10b is removed from outlet cover 10 as described above, each of first portion 10a and second portion 10b is large enough that it is not easily misplaced and does not present a choking hazard to children.

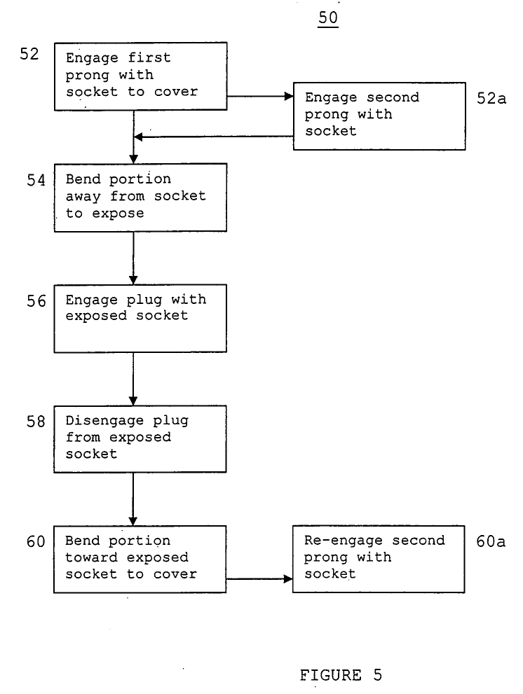

Now referring to FIG. 5, a method 50 of using outlet cover 10 is illustrated. According to the method, at step 52 a first prong, such as prong 30b, of the outlet cover 10 is engaged with a socket of an electrical outlet thereby covering one or more of the sockets of the electrical outlet. Step 52 may optionally include step 52a, at which step a second prong, such as prong 30a, of outlet cover 10 is engaged with a second socket of the electrical outlet. At step 54, a portion of the outlet cover 10, such as first portion 10a, is bent away from a socket of the electrical outlet, in this case an upper socket, in order to expose the socket. If prong 30a was engaged with the upper socket at step 52, then it is disengaged at step 54. At step 56, a plug of an electric device is engaged with the exposed socket, whereby the electric device can be used. The first prong remains engaged with the socket of the electrical outlet, thereby retaining a second portion of outlet cover 10, such as second portion 10b, in a position covering the lower socket, not in use. At step 58, when the electric device is no longer in use, the plug of the electric device is removed from the upper socket of the electrical outlet. At step 60, the first portion of the outlet cover 10, such as first portion 10a, is bent back towards the electrical outlet; thereby, covering the exposed socket. If a second prong was engaged with a second socket of the electrical outlet at step 52, then step 60 should include step 60a, wherein the second prong, such as prong 30a, of outlet cover 10 is re-engaged with the second socket, such an upper socket of the electric outlet.

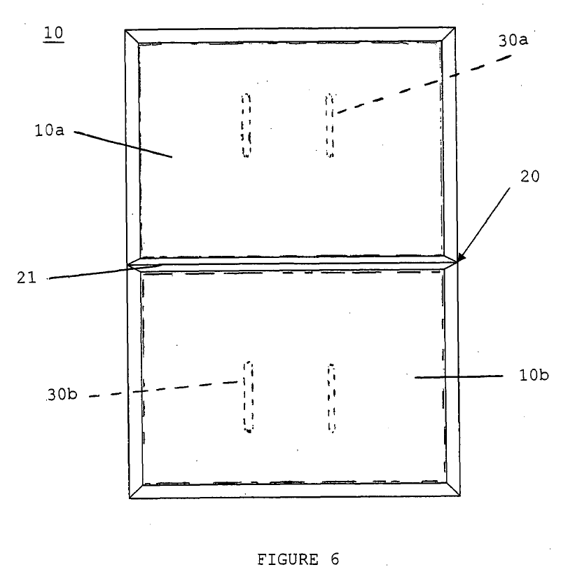

Referring now to FIG. 6, an alternate configuration of outlet cover 10 is illustrated wherein outlet cover 10 comprises a generally rectangular body. Outlet cover 10 preferably includes first portion 10a and second portion 10b separated by hinging means 21, such s in the form of groove 20. Outlet cover 10 preferably includes prongs 30a and 30b formed on first portion 10a and second portion 10b, respectively. Each of prongs 30a and 30b preferably comprise one or more projection adapted to engage a socket of an electrical outlet. Biasing means 40 takes the form of resilient material proximate hinging means 21, wherein such material preferable provides a biasing force biasing first portion 10a and second portion 10b in a generally co-planar arrangement.

Having, thus, described exemplary embodiments of the present invention, it should be noted by those skilled in the art that the within disclosures are exemplary only and that various other alternatives, adaptations, and modifications may be made within the scope and spirit of the present invention. Accordingly, the present invention is not limited to the specific embodiments as illustrated herein, but is only limited by the following claims.

What is claimed is at least:

1. A protective outlet cover comprising:
a planar body having a transverse groove therein; and
at least one projection adapted to engage a first socket of an electrical outlet such that said planar body is retained in a position covering at least one socket of the electrical outlet;
wherein said planar body is bendable along a line defined by said groove such that at least one socket of the electrical outlet is exposed while said at least one projection engages the first socket.

2. The protective outlet cover of claim 1, wherein said projection is a removable insert.

3. The protective outlet cover of claim 1, wherein said outlet cover comprises an electrically insulating material.

4. The protective outlet cover of claim 1, wherein said at least one projection comprises a pair of prongs adapted to engage the electrical outlet, said pair of prongs being disposed on a first portion of said outlet cover, said first portion defined by said groove.

5. The protective outlet cover of claim 1, wherein said at least one projection comprises two pairs of prongs adapted to engage respective sockets of the electrical outlet, said two pairs of prongs being disposed on respective portions of said outlet cover, said portions being defined by said groove.

6. The protective outlet cover of claim 1, wherein said at least one projection includes a relief portion for hinged removal of said at least one projection from engagement with the socket.

7. The protective outlet cover of claim 6, wherein said relief portion comprises a relief cut on an edge of said at least one projection.

8. The protective outlet cover of claim 6, wherein said relief portion comprises a short length of said at least one projection.

9. The protective outlet cover of claim 6, wherein said relief portion comprises a flexible material comprising said at least one projection.

10. A method of using an outlet cover comprising the steps of:
engaging a projection of said outlet cover with a socket of an electrical outlet; and
bending said outlet cover along a line defined by a groove in said outlet cover, thereby exposing a second socket of the electrical outlet.

11. The method of claim 10, further comprising the step of engaging a plug of an electric device with the exposed socket.

12. The method of claim 11, further comprising the steps of:
disengaging the plug of the electric device from the exposed socket; and
bending said outlet cover back along said line, thereby covering the exposed socket of the electrical outlet.

13. The method of claim 10, wherein said projection remains engaged with the socket of the electrical outlet during the bending step.

14. The method of claim 10, wherein said projection comprises a relief portion for hinged removal of said at least on projection from engagement with the socket.

15. The method of claim 10, wherein said projection comprises a relief cut on an edge of said at least one projection.

16. The method of claim 10, wherein said projection comprises short length.

17. The method of claim 10, wherein said projection comprises a flexible material.

18. A protective outlet cover for use with an electrical outlet comprising:
a planar body having a front face and a back face, said planar body having a transverse groove disposed therein;
at least one protrusion adapted to engage a first socket of an electrical outlet such that said planar body is retained in a position covering at least one socket of the electrical outlet;
wherein said planar body is bendable along a line defined by said groove such that at least one socket of the electrical outlet is exposed while said at least one protrusion engages the first socket.

19. The protective outlet cover of claim 18, wherein said outlet cover comprises a non-conductive, resilient material.

20. The protective outlet cover of claim 18, further comprising a spring mechanism operable to provide a biasing force to oppose bending along said line.
